(19) United States
(12) Patent Application Publication
(10) Pub. No.: US 2024/0025056 A1
(43) Pub. Date: Jan. 25, 2024

(54) PICK-AND-PLACE APPARATUS AND HEAD MATERIAL THEREOF

(71) Applicant: TAIWAN SEMICONDUCTOR MANUFACTURING COMPANY LTD., HSINCHU (TW)

(72) Inventor: JEN-YUAN CHANG, HSINCHU CITY (TW)

(21) Appl. No.: 17/814,553

(22) Filed: Jul. 25, 2022

(51) Int. Cl. B25J 15/06; B25J 15/00

(52) U.S. Cl. CPC B25J 15/0616; B25J 15/0052

(57) ABSTRACT

A pick-and-place apparatus includes a first head part, a vacuum system and a second head part. The first head part includes a first portion with a first material, a second portion surrounding the first portion and with a second material. The second head part is disposed between the first head part and the vacuum system. The pick-and-place apparatus further includes a plurality of vacuum holes. The plurality of vacuum holes penetrate through the first head part and the second head part to couple to the vacuum system. A hardness of the first material is greater than a hardness of the second material, and a bottom surface of the first portion and a bottom surface of the second portion are aligned with each other.

### BACKGROUND

The manufacturing of integrated circuits often involves the bonding of semiconductor chip to package substrates. With the evolving of semiconductor technologies, sizes of semiconductor chip are becoming increasingly smaller and thinner. The packaging of the semiconductor chip becomes more difficult due to the reduced size of semiconductor chip.

The accuracy in the placement of the semiconductor chip on the package substrate needs to be well controlled to maintain the yield of the bonding process. As the sizes continue to decrease, packaging processes continue to become more difficult to perform. Thus, there is a challenge to improve the tools applicable for the semiconductor devices of smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion,

FIG. 1 illustrates a schematic drawing of a pick-and-place apparatus according to some embodiments of the present disclosure.

FIG. 2 illustrates a schematic cross-section view of the pick-and-place apparatus according to some embodiments of the present disclosure.

FIG. 3 illustrates a schematic drawing of a bonding interface according to some embodiments of the present disclosure.

FIGS. 4A-4C illustrate a schematic bottom view of the first head part of a pick-and- place apparatus according to aspects of one or more embodiments of the present disclosure.

FIG. 5A illustrates a schematic bottom view of the first head part of a pick-and-place apparatus according to aspects of one or more embodiments of the present disclosure.

FIG. 5B illustrates schematic side views of a semiconductor chip according to aspects of one or more embodiments of the present disclosure.

FIG. 6 illustrates a schematic bottom view of the first head part of a pick-and-place apparatus according to aspects of one or more embodiments of the present disclosure.

FIG. 7 illustrates a schematic bottom view of the first head part of a pick-and-place apparatus according to aspects of one or more embodiments of the present disclosure.

FIG. 8A illustrates a schematic - bottom view of the first head part of a pick-and-place apparatus according to aspects of one or more embodiments of the present disclosure.

FIG, 8B illustrates schematic side views of a semiconductor chip according to aspects of one or more embodiments of the present disclosure.

FIG. 9 illustrates a schematic bottom view of the first head part of a pick-and-place apparatus according to aspects of one or more embodiments of the present disclosure.

FIG. 10 illustrates a schematic bottom view of the first head part of a pick-and-place apparatus according to aspects of one or more embodiments of the present disclosure.

FIG. 11 illustrates a schematic cross-section view of the pick-and-place apparatus according to some embodiments of the present disclosure.

FIG. 12 illustrates a schematic cross-section view of the pick-and-place apparatus according to some embodiments of the present disclosure.

FIGS. 13A-13C illustrate a schematic bottom view of the first head part of a pick-and- place apparatus according to aspects of one or more embodiments of the present disclosure.

FIGS. 14A-14B illustrate a schematic cross-section view of the pick-and-place apparatus according to aspects of one or more embodiments of the present disclosure.

FIG. 15 illustrates a schematic cross-section view of the pick-and-place apparatus according to some embodiments of the present disclosure.

FIG. 16A illustrates a schematic bottom view of the first protrusions of a pick-and- place apparatus according to aspects of one or more embodiments of the present disclosure.

FIG. 16B illustrates a schematic bottom view of the first protrusions and the second protrusions of a pick-and-place apparatus according to aspects of one or more embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly.

As used herein, although terms such as “first,” “second” and “third” describe various elements, components, regions, layers and/or sections, these elements, components, regions, layers and/or sections are not limited by these terms. These terms are used to distinguish one element, component, region, layer, or section from another. Terms such as “first,” “second” and “third” in response to used herein do not imply a sequence or order unless clearly indicated by the context.

Notwithstanding that the numerical ranges and parameters setting forth the broad scope of the disclosure are approximations, the numerical values set forth in the. specific examples are reported as precisely as possible. Any numerical value, however, inherently contains certain errors necessarily resulting from the standard deviation found in the respective testing measurements. Also, as used herein, the terms “substantially,” “approximately” and. “about” generally mean within a value or range that is contemplated by people having ordinary skill in the art. Alternatively, the terms “substantially,” “approximately” and “about” mean within an acceptable standard error of the mean in response to considered by one of ordin.ary skill in the art. People having ordinary skill in the art understand that the acceptable standard error varies according to different technologies. Other than in the operating/working examples, or unless otherwise expressly specified, the numerical ranges, amounts, values, and percentages such as those for quantities of materials, durations of times, temperatures, operating conditions, ratios of amounts, and the likes thereof disclosed herein should be understood as modified in instances by the terms “substantially,” “approximately” or “about.” Accordingly, unless indicated to the contrary, the numerical parameters set forth in the present disclosure and attached claims are approximations that vary as desired. At the very least, each numerical parameter is construed considering the number of reported significant digits and by applying ordinary rounding techniques. Ranges are expressed herein as from one endpoint to another endpoint or between two endpoints. All ranges disclosed herein are inclusive of the endpoints, unless otherwise specified.

A pick-and-place apparatus picks up a semiconductor chip and then places on a wafer. In some comparative approaches, the pick-and-place apparatus includes a head (or a tip) contacting the semiconductor chip. The head with a single vacuum hole to suck the semiconductor chip, the radius of the single vacuum hole is relatively large. The disadvantage of this pick-and-place apparatus is that the center of the semiconductor chip will warp upward during the pick-and-place process. The peripheral part of the semiconductor chip will first touch the wafer, then the rest of the semiconductor chip. This will cause the bonding untight between the semiconductor wafer or semiconductor device during the place process, which adversely affects the yield of the packaging. To improve the bonding tightness, the pick-and-place apparatus of the semiconductor needs to be improved,

Embodiments of a pick-and-place apparatus is therefore provided. Throughout the various views and illustrative embodiments, like reference numbers are used to designate like elements. It should be appreciated, however, that the embodiments provide many applicable concepts that can be embodied in a wide variety of specific contexts. The specific embodiments discussed are merely illustrative, and do not limit the scope of the disclosure.

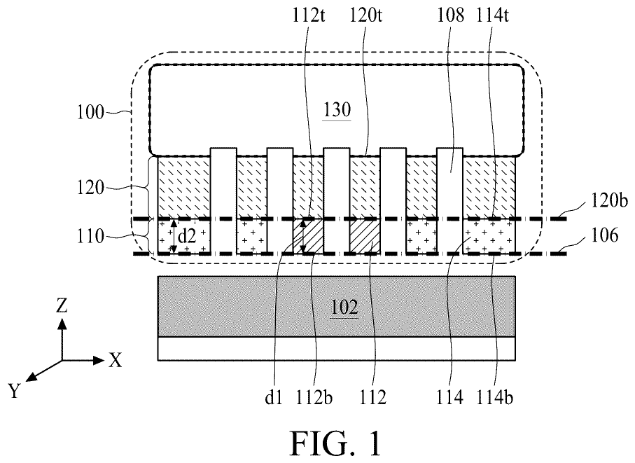

FIG. 1 illustrates a schematic cross-section view of the pick-and-place apparatus 100 according to some embodiments of the present disclosure. In some embodiments, the pick-and-place apparatus 100 includes a first head part 110, a second head part 120 and a vacuum system 130. In some embodiments, the first head part 110 includes a first portion 112 with a first material, and a second portion 114 with a second material. The second portion 114 is surrounding the first portion 112. In some embodiments, a hardness of a first material of the first portion 112 is greater than a hardness of a second material of the second portion 114. In some embodiments, a high hardness difference between the first material and the second material is greater than 0.1%, but the disclosure is not limited thereto. The Young's coefficient difference between the first material and the second material is greater than 0.1%, but the disclosure is not limited thereto. In some embodiments, the first material includes metals such as aluminum, copper or the like. In some embodiments, the second material includes soft materials such as soft rubber, or the like which is easy to deform. In some embodiments, the soft feature of the second material of the second portion 114 may seal the vacuum during the vacuum system 130 operating. The equal external force variation sequence can be the second material (such as soft rubber) greater than the first material (such as aluminum).

In some embodiments, a surface area of the first portion 112 may be smaller than a surface area of the second portion 114. As shown in FIG. 1, a bottom surface 112b of the first portion 112 and a bottom surface 114b of the second portion 114 are aligned with each other before the pick-and-place apparatus 100 sucks a semiconductor chip 102. In such embodiments, a thickness di of the first portion 112 and a thickness d2 of the second portion 114 are the same when the pick-and-place apparatus 100 leaves the semiconductor chip. In some embodiments, a top surface 1121 of the first portion 112 and a top surface 114t of the second portion 114 are coupled to the second head part 120.

Referring to FIG. 1, in some embodiments, the second head part 120 couples the first head part 110 with the vacuum system 130. In some embodiments, the second head part 120 includes a third material which is similar to the first material, such as aluminum, copper or the like. In some embodiments, the third material of the second head part 120 may function as a. support against to the first head pail 110 when the pick-and-place apparatus 100 press the semiconductor chip 102. In some embodiments, the third material the second head part 120 may be similar to the second material, such as soft rubber, or other material which is easy to deform. During the pick-and-place process, the vacuum system 130 may be coupled to the pick-and-place apparatus 100 and may be used to suck and secure the semiconductor chip 102.

As illustrated in FIG. 1, the pick-and-place apparatus 100 further includes a plurality of vacuum holes 108. The plurality of vacuum holes 108 penetrate through the first head part 110 and the second head part 120 to couple to the vacuum system 130. In addition, a pump of the vacuum system 130 may be used to suck the semiconductor chip 102 by exerting vacuum force through the vacuum holes 108.

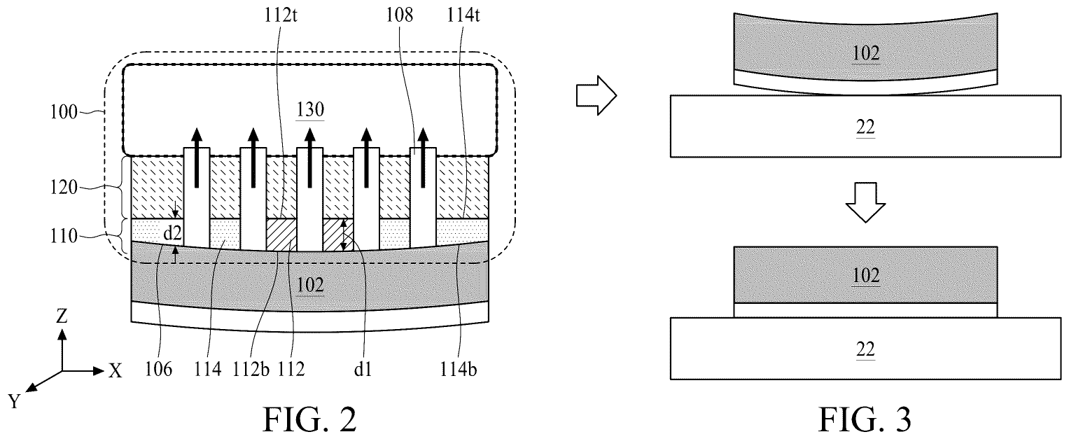

FIG. 2 illustrates a schematic cross-section view of the pick-and-place apparatus 100 according to some embodiments of the present disclosure. In some embodiments, during the vacuum system 130 operation, the thickness d2 of the second portion 114 changes when the bottom surface 114b of the second portion 114 is in contact with the semiconductor chip 102 while the thickness d1 of the first portion 112 keep unchanged, and the bottom surface 106 of the first head part 110 presents elastic deformation. In some embodiments, the top surface 112t and the top surface 114t are aligned with each other even when the first head part 110 deformed. When the pick-and-place apparatus 100 is in contact with the semiconductor chip 102 during the vacuum system 130 operation, the suction through the vacuum holes 108 generates a negative pressure to suck the semiconductor chip 102. As described above, the first head part 110 is composited with different materials, the second material is softer than the first material. During the vacuum system 130 operation, the first material of the first portion 112 press against the semiconductor chip 102, while second material of the second portion 114 absorbs the pressure from the semiconductor chip 102. In such embodiments, the thickness di of the first portion 112 may be consistent while the thickness d2 of the second portion 114 is inconsistent. The semiconductor chip 102 is therefore deformed to present a curve as shown in FIG. 2.

In some embodiments, as shown in FIG. 3, a lowest point (e.g. central point) of the curved semiconductor chip 102 is in contact with the wafer 22. then the rest of the semiconductor chip 102 when the pick-and-place apparatus 100 places the semiconductor chip. The deformation may help the semiconductor chip 102 to be bonded to the wafer 22 tightly. Thus a gap or a void issue in the central region is mitigated. In some embodiments, a warpage of the semiconductor chip 102 is greater than 0.1 μm, for example from about 1 μm to 15 μm, but the disclosure is not limited thereto.

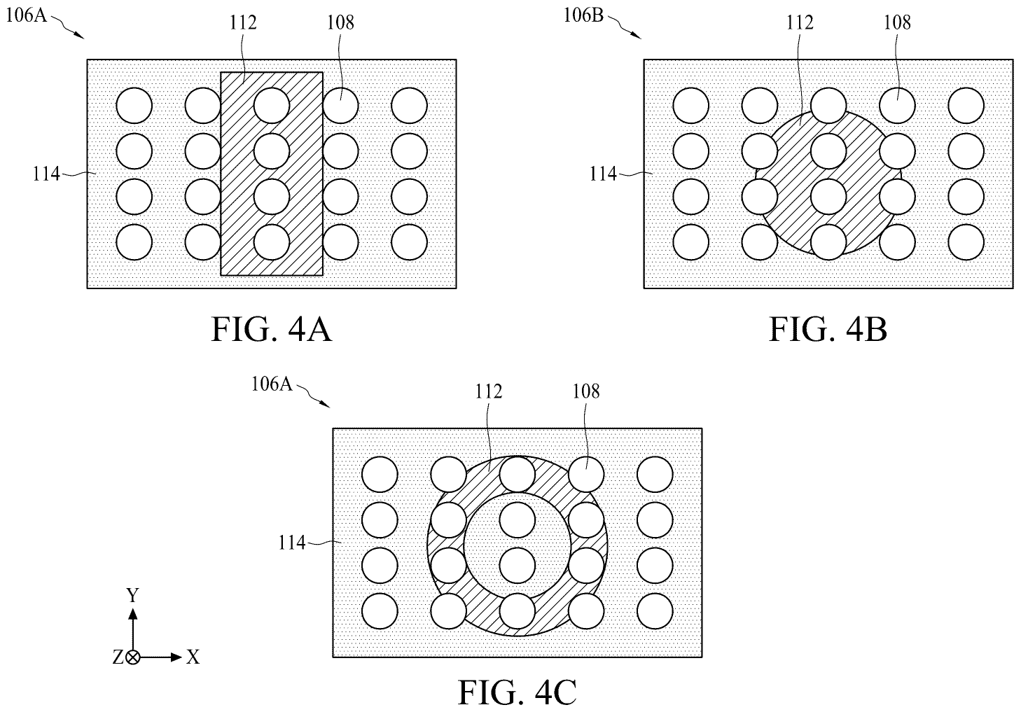

FIGS. 4A to 4C illustrate a bottom view of the first head part 110 of the pick-and-place apparatus 100 according to some embodiments of the present disclosure. As shown in FIGS. 4A to 4C, the plurality of vacuum holes 108 are arranged to form a column-and-row array. In some entbodiments, FIG. 4A shows the bottom surface 106A of the first head part 110, each of the first portion 112 and the second portion 114 has a rectangular shape. Some of the vacuum holes 108 are entirely disposed in the first portion 112 and others vacuum holes 108 are entirely disposed in the second portion. In some embodiments, FIG. 4B shows the bottom surface 106B of the first head part 110, the first portion 112 has a circular shape, and the second portion 114 has a rectangular shape. In some embodiments, at least one of the vacuum holes 108 is entirely disposed in the first portion 112, and at least one of the vacuum holes 108 is partially in the first portion 112 and partially in the second portion 114. In some embodiments, FIG. 4C shows the bottom surface 106C of the first head part 110, the first portion 112 as a ring shape disposed in the center of the bottom surface 106C of the first head part 110, and the second portion 114 has a rectangular shape. In some embodiments, a circle portion of the second portion 114 is disposed in the center of the ring. In some embodiments, at least one of the vacuum holes 108 is entirely disposed in the circle portion of the second portion 114, and at least one of the vacuum holes 108 is partially in the ring shape of the first portion 112 and partially in the second portion 114.

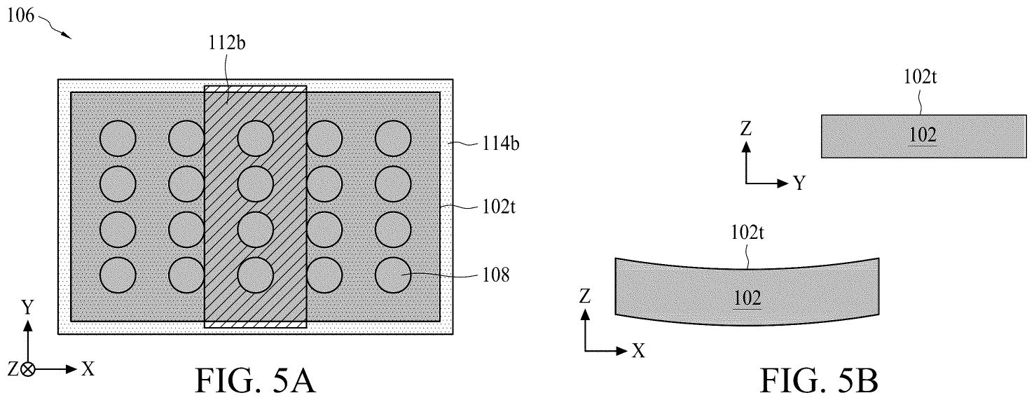

FIG. 5A illustrates a bottom view of the first head part 110 of the pick-and-place apparatus 100 according to aspects of one or more embodiments of the present disclosure. In some embodiments, as shown in FIG. 5A, an area of the semiconductor chip 102 is smaller than an area of the bottom surface 106 of the first head part 110. As shown in FIG. 5A, two sides of the bottom surface 112b of the first portion 112 exceed the semiconductor chip along the y-direction, a portion of the bottom surface 114b of the second portion 114 exceeds the semiconductor chip along the peripheral border. The bottom surface 112b of the first portion 112 and the bottom surface 114b of the second portion 114 are aligned symmetrically as shown in FIG. 5A,

FIG. 5B illustrates schematic side views of a semiconductor chip according to aspects of one or more embodiments of the present disclosure. In some embodiments, when the semiconductor chip is deformed, a first side view of the semiconductor chip 102 may be a. rectangle shape at y-z, plane and a second side view of the semiconductor chip 102 may be a curve at x-z plane as shown in FIG. 5B,

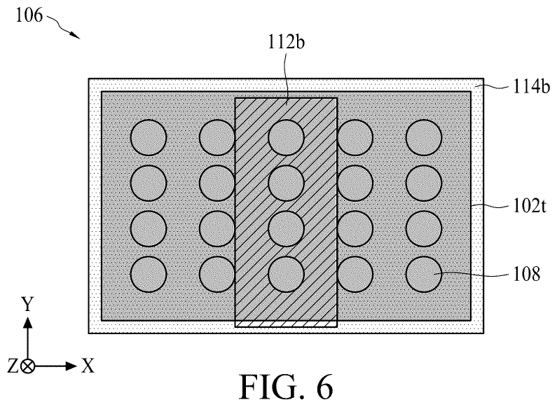

In some embodiments, as shown in FIG. 6, one side of the bottom surface 112b of the first portion 112 exceeds the semiconductor chip along the y-direction. The bottom surface 112b of the first portion 112 is asymmetrically as shown in FIG. 6. The first side view and the second side view of the semiconductor may present as shown in FIG. 5B.

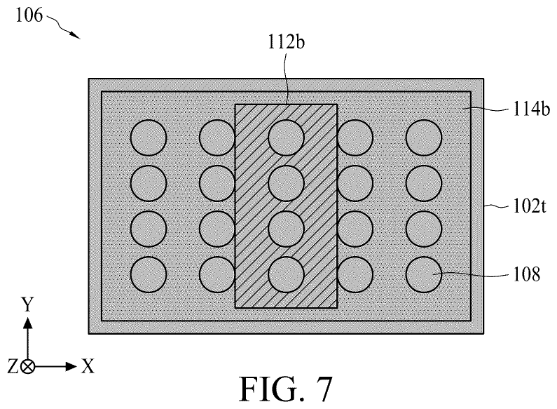

In some embodiments, as shown in FIG. 7, the area of the semiconductor chip 102 is greater than the area of the bottom surface 106 of the first head part 110. The bottom surface 112b of the first portion 112 and the bottom surface 114b of the second portion 114 are aligned symmetrically as shown in FIG. 7. The first side view and the second side view of the semiconductor may present as shown in FIG. 5B.

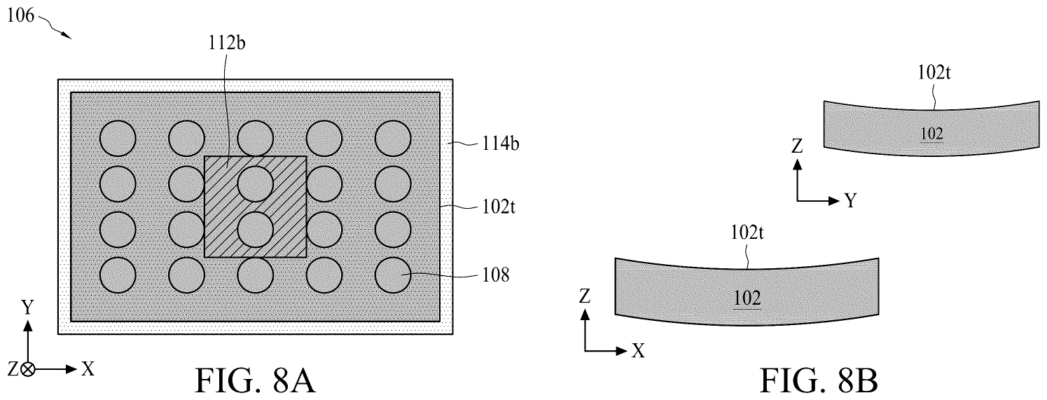

In some embodiments, as shown in FIG. 8A, the area of the semiconductor chip 102 is smaller than the area of the bottom surface 106 of the first head part 110. The bottom surface 112b of the first portion 112 is square. The bottom surface 112b of the first portion 112 and the bottom surface 114b of the second portion 114 are aligned symmetrically as shown in FIG. 8A.

FIG. 8B illustrates schematic side views of a semiconductor chip according to aspects of one or more embodiments of the present disclosure. In some embodiments, when the semiconductor chip is deformed, the first side and the second side views of the semiconductor chip 102 may be a circular arc curve as shown in FIG. 8B.

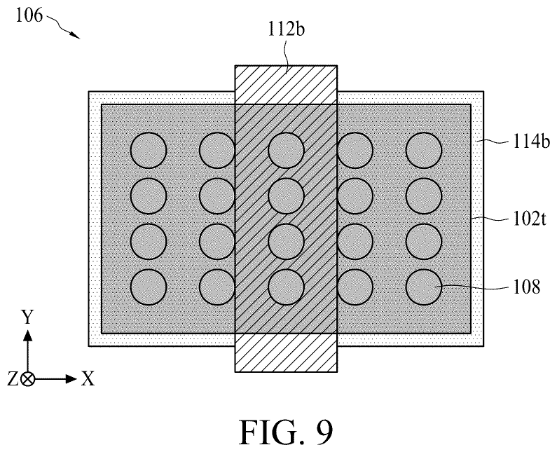

In some embodiments, as shown in FIG. 9, the area of the semiconductor chip 102 is smaller than the area of the bottom surface 106 of the first head part 110. As shown in FIG. 9, two sides of the bottom surface 112b of the first portion 112 exceed the bottom surface 106 along the y-direction. The bottom surface 112b of the first portion 112 and the bottom surface 114b of the second portion 114 are aligned symmetrically as shown in FIG. 9. The first side view and the second side view of the semiconductor may present as shown in FIG. 5B.

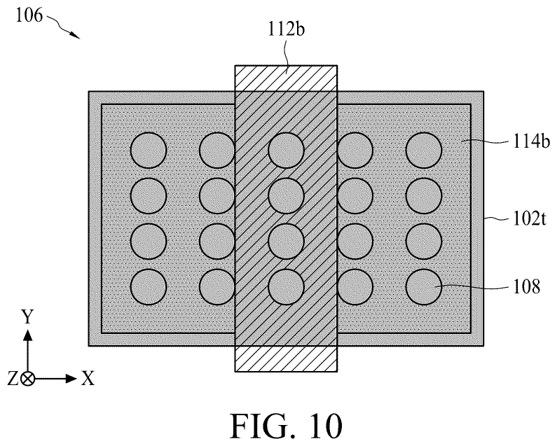

In some embodiments, as shown in FIG. 10, the area of the semiconductor chip 102 is greater than the area of the bottom surface 106 of the first head part 110. As shown in FIG. two sides of the bottom surface 112h of the first portion 112 exceed the bottom surface 106 along the y-direction. The bottom surface 112b of the first portion 112 and the bottom surface 114b of the second portion 114 are aligned symmetrically as shown in FIG. 10. The first side view and the second side view of the semiconductor may present as shown in FIG. 5B.

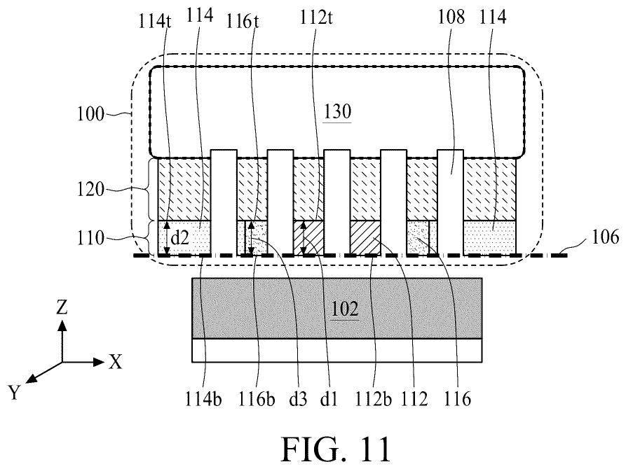

FIG. 11 illustrates a schematic cross-section view of the pick-and-place apparatus 100 according to some embodiments of the present disclosure. In some embodiments, the pick-and-place apparatus 100 includes a first head part 110, a second head part 120 and a vacuum system 130. In some embodiments, the first head part 110 includes a first portion 112 disposed in a central region of the first head part 110, a second portion 114 surrounding the central region and a third portion 116 disposed between the first portion 112 and the second portion 114. In some embodiments, a hardness of a first material of the first portion 112 is greater than a. hardness of a third material of the third portion 116, and the third hardness of the third material of the portion 116 is greater than a hardness of a second material of the second portion 114. The high hardness difference between the first material of the first portion 112 and the second material of the second portion 114 is greater than 0.1%, but the disclosure is not limited thereto. In some embodiments, the high hardness difference between the first material of the first portion 112 and the third material of the third portion 116 is greater than 0.1%, but the disclosure is not limited thereto. The Young's coefficient difference between the first material of the first portion 112 and the second material of the second portion 114 is greater than 0.1%, but the disclosure is not limited thereto, The Young's coefficient difference between the first material of the first portion 112 and the third material of the third portion 116 is greater than 0.1%, but the disclosure is not limited thereto. In some embodiments, the first material includes metals such as aluminum, copper or the like. In some embodiments, the second material includes soft materials such as soft rubber, or the like which is easy to deform. In some embodiments, the third material includes plastic such as plastic or epoxy resin or the like which is not easy to deform. In some embodiments, the soft feature of the second material of the second portion 114 may seal the vacuum during the vacuum system 130 operating. The equal external force variation sequence can be the second material (such as soft rubber) greater than the third material (such as plastic) greater than the first material (such as aluminum).

Referring to FIG. 11, in some embodiments, a surface area of the first portion 112 may be smaller than a surface area of the second portion 114 and a surface area of the third portion 116, In some embodiments, a bottom surface 112b of the first portion 112 of the first portion 112, a bottom surface 114b of the second portion 114 and a bottom surface116b of the third portion 116 are aligned with each other before the pick-and-place apparatus 100 sucks a semiconductor chip 102, the thickness of the first head part 110 is consistent, as shown in FIG. 11, In some embodiments, a thickness d2 of the second portion 114 and a thickness d3 of the third portion 116 are the same when the pick-and-place apparatus 100 leaves the semiconductor chip. In some embodiments, a top surface 112t of the first portion 112, a top surface 114t of the second portion 114 and a top surface 116t of the third portion 116 are coupled to the second head part 120,

In some embodiments, the second head part 120 couples the first head part 110 with the vacuum system 130. In some embodiments, the second head part 120 includes a fourth material which is similar to the first material, such as aluminum, copper or the like. In some embodiments, the fourth material of the second head part 120 may function as a support against to the first head part 110 when the pick-and-place apparatus 100 press the semiconductor chip 102. In some embodiments, the third material the second head part 120 may be similar to the second material, such as soft rubber, or other material which is easy to deform. During the pick-and-place process, the vacuum system 130 may be coupled to the pick-and-place apparatus 100 and may be used to suck and secure the semiconductor chip 102.

In some embodiments, as illustrated in FIG. 11, the pick-and-place apparatus 100 further includes a plurality of vacuum holes 108. The plurality of vacuum holes 108 penetrate through the first head part 110 and the second head part 120 to couple to the vacuum system 130. In addition, a pump of the vacuum system 130 may be used to suck the semiconductor chip 102 by exerting vacuum force through the vacuum holes 108.

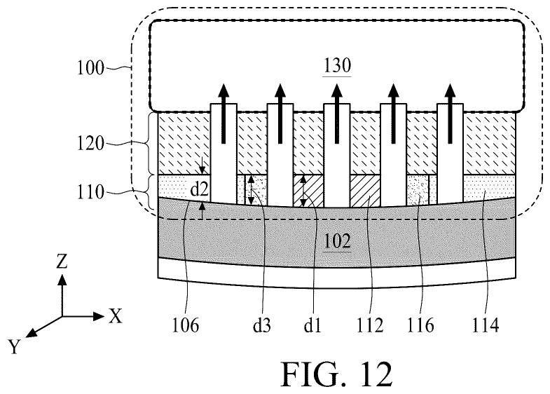

FIG. 12 illustrates a schematic cross-section view of the pick-and-place apparatus 100 according to some embodiments of the present disclosure. In some embodiments, during the vacuum system 130 operation, a thickness d2 of the second portion 114 and a thickness d3 of the third portion 116 change when the bottom surface 114b of the second portion 114 and the bottom surface 116b of the third portion 116 are in contact with the semiconductor chip 102 while a thickness d1 of the first portion 112 keep unchanged, and the bottom surface 106b of the first head part 110 presents elastic deformation, as shown in FIG. 12.When the pick-and-place apparatus 100 is in contact with the semiconductor chip 102 during the vacuum system 130 operation, the suction through the vacuum holes 108 generates a negative pressure to suck the semiconductor chip 102. The first material of the first portion 112 press against and deform the semiconductor chip 102 and present a curve. The lowest point (e.g. central point) of the curved semiconductor chip 102 will first touch the wafer, then the rest of the semiconductor chip 102 when the pick-and-place apparatus 100 places the semiconductor chip. The deformation may help the semiconductor chip 102 to be bonded to the water tightly. Thus a gap or a void issue in the central region is mitigated. In some embodiments, a warpage of the semiconductor chip 102 is greater than 0.1 μm, for example from about 1 μm to 15 μm, but the disclosure is not limited thereto.

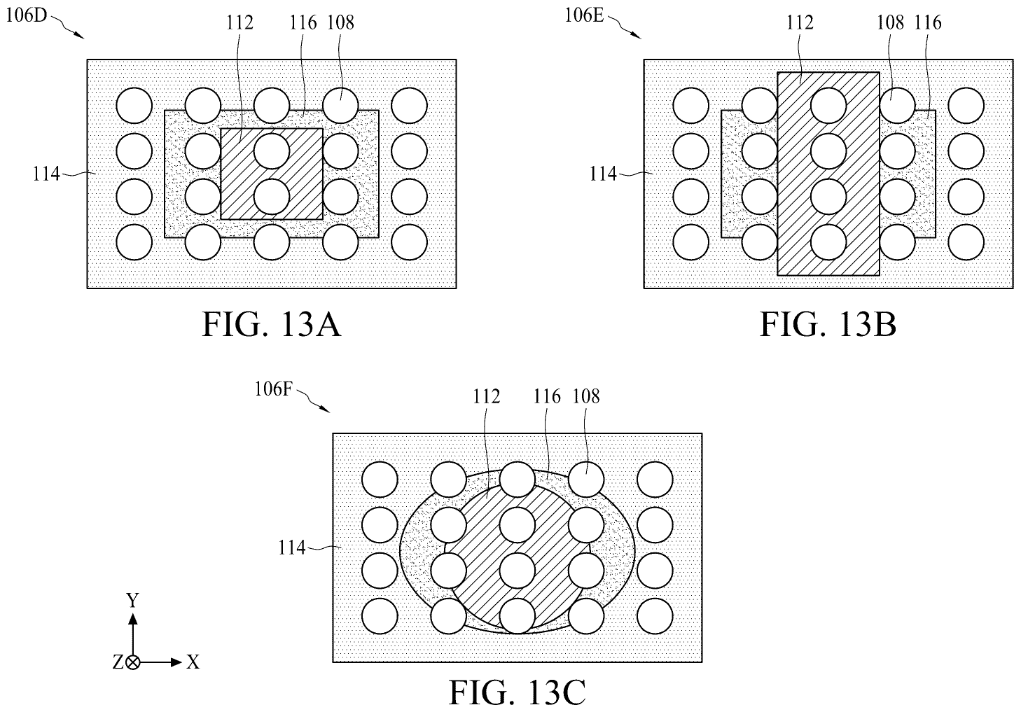

FIGS. 13A-13B illustrate a bottom view of the pick-and-place apparatus 100 according to some embodiments of the present disclosure. As shown in FIGS. 13A-13B, the plurality of vacuum holes 108 are arranged to form a column-and-row array. In some embodiments, FIG. 13A shows the bottom surface 1061) of the first head part 110. Each of the first portion 112, the second portion 114 and the third portion 116 has a rectangular shape from a bottom view. The area of the bottom surface 112b of the first portion 112 is smaller than the area of the bottom surface 116b of the third portion 116. In some embodiments, at least one of the vacuum holes 108 is entirely disposed in the first portion 112, and at least one of the vacuum holes 108 is partially in the first portion 112, partially in the second portion 114 and partially in the second portion 116. In some embodiments, FIG. 13B shows the bottom surface 106E of the first head part 110. Each of the first portion 112, the second portion 114 and the third portion 116 has a. rectangular shape from a bottom view. In some embodiments, two sides of the bottom surface 112b of the first portion 112 exceed the bottom surface 1161) of the third portion 116, and two sides of the bottom surface 1161) of the third portion 116 exceed the bottom surface 112b of the first portion 112 as shown in FIG. 13B. In some embodiments, at least one of the vacuum holes 108 is entirely disposed in the first portion 112, and at least one of the vacuum holes 108 is partially in the first portion 112, partially in the second portion 114 and partially in the second portion 116. In some embodiments, FIG. 13C shows the bottom surface 106F of the first head part 110. Each of the first portion 112 and the third portion 116 has a circular shape and the second portion 114 has a rectangular shape as shown in FIG. 13C. The area of the bottom surface 112b of the first portion 112 is smaller than the area of the bottom surface 116b of the third portion 116. In some embodiments, at least one of the vacuum holes 108 is entirely disposed in the first portion 112, and at least one of the vacuum holes 108 is partially in the first portion 112, partially in the second portion 114 and partially in the second portion 116.

The embodiments illustrated in FIGS. 5A through 10 as described above may also applied to the various aspects of embodiments illustrated in FIG. 11. One or more embodiments shown in FIGS. 5A through 10 are already discussed in the aforementioned embodiments.

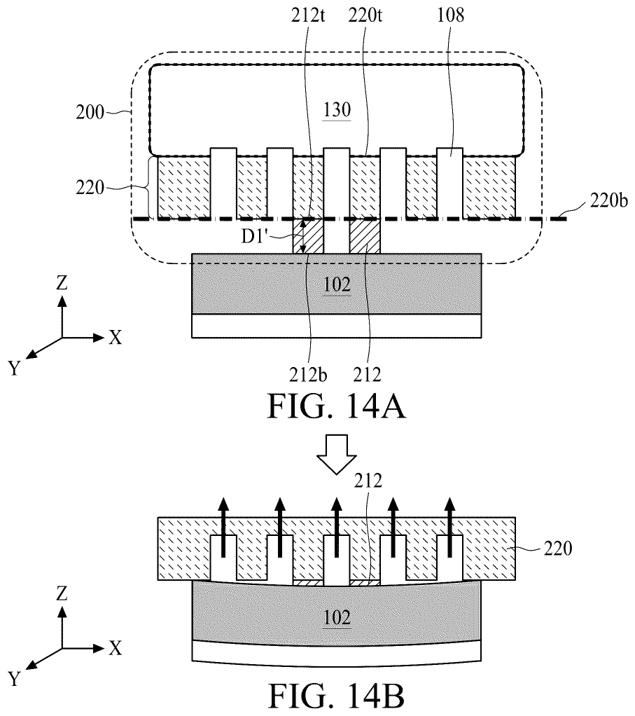

FIGS. 14A-14B illustrate a schematic cross-section view of the pick-and-place apparatus 200 according to aspects of one or more embodiments of the present disclosure. In some embodiments, as shown in FIG. 14A, the pick-and-place apparatus 200 includes a plurality of first protrusions 212. a head 220 and a vacuum system 130. The first protrusions 212 are disposed over a central region and protrudes from the head 220. Each of the first protrusions 212 has a top surface 2121 in contact with the bottom surface 220b of the head 220 and a bottom surface 212b of the first portion 212 opposite to the top surface 2121. In some embodiments, the first protrusions 212 include a first material which is different from a second material of the head 220. In some ethbodiments, a hardness of the second material of the head 220 may be greater than a hardness of the first material of the first protrusions 212. In some embodiments, the first material is replaceable if the first protrusions 212 is worn. In some embodiments, the material of the head 220 may be same as the first material of the first protrusions 212. In some embodiments, the first material includes flexible materials such as tape, or the like. In some embodiments, the second material includes metals such as aluminum, copper or the like.

Referring to FIG. 14A, a step-height is formed between the bottom surface 220b of the head 220 and the bottom surfaces 212b of the first portion 212 of the first protrusions 212. When the pick-and-place apparatus 200 is in contact with the semiconductor chip 102 during the vacuum system 130 operation, the suction through the vacuum holes 108 generates a negative pressure to suck the semiconductor chip 102, the first protrusions 212 press against the semiconductor chip 102 and make the semiconductor chip 102 deform. The features of the step-height shape makes the semiconductor chip 102 deformed and present a curve, as shown in FIG. 14B. The warpage of the semiconductor chip 102 is greater than 0.1 μm, for example from about 1 μm to 15 μm, but the disclosure is not limited thereto.

As illustrated in FIGS. 14A and 14B, the pick-and-place apparatus 200 further includes a plurality of vacuum holes 108. The plurality of vacuum holes 108 penetrate through the head 220 and the first protrusions 212 from the bottom surface 220b of the head 220 and the bottom surface 212b of the first portion 212 to the vacuum system 130. In addition, a pump of the vacuum system 130 may be used to suck the semiconductor chip 102 by exerting vacuum force through the vacuum holes 108.

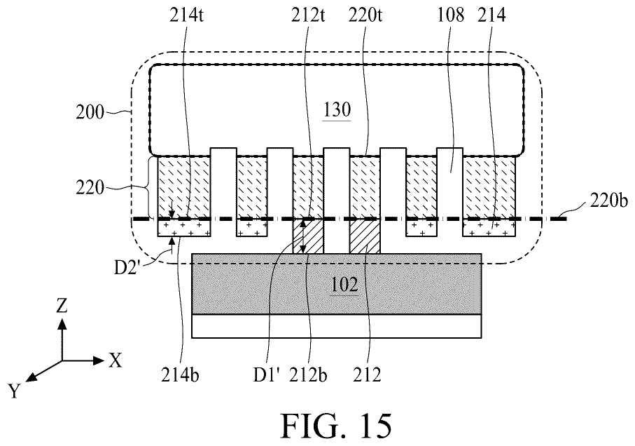

FIG. 15 illustrates a schematic cross-section view of the pick-and-place apparatus 200 according to some embodiments of the present disclosure. In some embodiments, the pick-and-place apparatus 200 further includes a plurality of second protrusions 214, where thicknesses D1′ of the first protrusions 212 is greater than thickness D2′ of the second protrusions 214, and a step-height is formed between bottom surfaces 214 of the second protrusions 214 and the bottom surfaces 212b of the first portion 212 of the first protrusions 212. In some embodiments, the second material of the second protrusions 214 includes soft materials such as soft rubber, or the like which is easy to deform, In some embodiments, a hardness of the first material of the first protrusions 212 is greater than a hardness of a second material of the second protrusions 214.

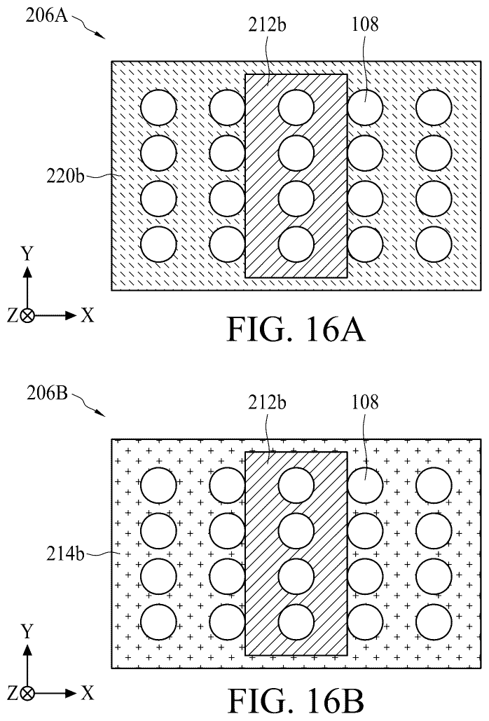

FIGS. 16A-16B illustrate a schematic bottom view of a pick-and-place apparatus 200 according to aspects of one or more embodiments of the present disclosure. As shown in FIGS. 16A-16B, the plurality of vacuum holes 108 are arranged to form a column-and-row array. In some embodiments, FIG. 16A shows a bottom surface 206A of the head 220, the bottom surfaces 212b of the first portion 212 has a rectangular shape and the first protrusions 212 are exposed from the bottom surface 220b of the head 220. In some embodiments, FIG. 14B shows a bottom surface 206B of the first protrusions 212 and the second protrusions 214, the bottom surfaces 212b of the first portion 212 has a rectangular shape and the first portion 212 are exposed from the bottom surface 214b of the second protrusions 214.

In some embodiments, the present disclosure provides a pick-and-place apparatus, the first head part of the pick-and-place apparatus includes different materials. The material disposed in a peripheral region of the first head part is softer than the material disposed in a center region of the first head part. The harder material disposed in the central region of the first head part presses against the semiconductor chip and makes the semiconductor chip deformed and present a curve. The lowest point (e.g. central point) of the curved semiconductor chip is in contact with the wafer, then the rest of the semiconductor chip when the pick-and-place apparatus places the semiconductor chip. Accordingly, gap issue or void issue between the semiconductor chip (such as system on integrate chip (SoIC)) and the wafer is mitigated.

As described in greater detail above, some implementations described herein provide a pick-and-place apparatus. A pick-and-place apparatus includes a first head part, a vacuum system, a second head part and a plurality of vacuum holes. The first head part includes a first portion including a first material, a second portion surrounding the first portion and including a second material. The second head part is disposed between the first head part and the vacuum system. The plurality of vacuum holes penetrate through the first head part and the second head part to couple to the vacuum system. A hardness of the first material is greater than a hardness of the second material, and a bottom surface of the first portion and a bottom surface of the second portion are aligned with each other.

As described in greater detail above, some implementations described herein provide a pick-and-place apparatus. A pick-and-place apparatus includes a first head part, a vacuum system, a second head part and a plurality of vacuum holes. The first head part includes a first portion disposing in a central region of the first head part and including a first material, a second portion including a second material and a third portion including a third material The third portion is disposed between the first portion and the second portion. The second portion is surrounding the first portion and the third portion. A central point of the third portion and a central point of the second portion are aligned with a central point of the first portion and including a third material. The second head part is disposed between the first head part and the vacuum system. The plurality of vacuum holes penetrate through the first head part and the second head part to couple to the vacuum system. A hardness of the first material is greater than a hardness of the third material, and the hardness of the third material is greater than a hardness of the second material, and a bottom surface of the first portion and a bottom surface of the second portion and a bottom surface of the third portion are aliizned with each other.

As described in greater detail above, some implementations described herein provide a pick-and-place apparatus. A pick-and-place apparatus includes a vacuum structure, a head, a plurality of vacuum holes and a plurality of first protrusions. The head is disposed over the vacuum structure, where the head has a first surface and a second surface opposite to the first surface. The plurality of vacuum holes penetrate through the head from the first surface to the second surface. The plurality of first protrusions is disposed over a central region of the head, where each of the plurality of the first protrusions has a first surface in contact with the second surface of the head and a second surface opposite to the first surface. The head includes a second material and the plurality of the first protrusions include a first material. A step-height is formed between the second surface of the head and the second surfaces of the plurality of the first protrusions,

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pick-and-place apparatus, comprising:
a first head part comprising:
a first portion comprising a first material; and
a second portion surrounding the first portion and comprising a second material;
a vacuum system;
a second head part disposed between the first head part and the vacuum system; and
a plurality of vacuum holes penetrating through the first head part and the second head part to couple to the vacuum system, wherein a hardness of the first material is greater than a hardness of the second material, and a bottom surface of the first portion and a bottom surface of the second portion are aligned with each other.

2. aratus of claim 1, wherein a top surface of the first portion and a top surface of the second portion are aligned with each other and coupled to the second head part.

3. aratus of claim 1, wherein a thickness of the second portion changes when the bottom surface of the second portion is in contact with a chip.

4. The apparatus of claim 1. wherein the plurality of vacuum holes are arranged to form a column-and-row array.

5. The apparatus of claim 1, wherein each of the first portion and the second portion has a rectangular shape from a bottom view.

6. The apparatus of Claim I, wherein the first portion has a circular shape, and the second portion has a rectangular shape from a bottom view.

7. The apparatus of claim 1. wherein the first portion as a ring shape, and the second portion has a rectangular shape from a bottom view.

8. The apparatus of claim 1, wherein the second head part comprises a third material, and a hardness of the third material is similar to the hardness of the first material and is greater than the hardness of the second material.

9. The apparatus of claim 1, wherein the second head part comprises a third material, and a hardness of the third material is similar to the hardness of the second material and is less than the hardness of the first material.

10. The apparatus of claim 1, wherein a surface area of the first portion is smaller than a surface area of the second portion.

11. A pick-and-place apparatus, comprising:
a first head part comprising:
a. first portion disposed in a central region of the first head part and comprising a first material:
a second portion comprising a second material; and
a third portion comprising a third material, wherein the third portion is disposed between the first portion and the second portion, wherein the second portion surrounding the first portion and the third portion, wherein a central point of the third portion and a central point of the second portion are aligned with a central point of the first portion and comprising a third material;
a vacuum system;
a second head part disposed between the first head part and the vacuum system; and
a plurality of vacuum holes penetrating through the first head part and the second head part to couple to the vacuum system, wherein a hardness of the first material is greater than a hardness of the third material, and the hardness of the third material is greater than a hardness of the second material, and a bottom surface of the first portion and a bottom surface of the second portion and a. bottom surface of the third portion are aligned with each other.

12. The apparatus of Claim 11, wherein a. top surface of the first portion and a top surface of the second portion and a top surface of the third portion are aligned with each other and coupled to the second head part.

13. The apparatus of claim 11, wherein a thickness of the second portion and a thickness of the third portion change when the bottom surface of the second portion and the bottom surface of the third portion are in contact with a chip.

14. The apparatus of claim 11, wherein each of the first portion and the second portion and the third portion has a rectangular shape from a bottom view.

15. ratus of claim 11, wherein each of the first portion and the third portion has a circular shape, and the second portion has a rectangular shape from a bottom view.

16. A pick-and-place apparatus, comprising:
a vacuum structure;
a head disposed over the vacuum structure, wherein the head has a first surface and a second surface opposite to the first surface;
a plurality of vacuum holes penetrating through the head from the first surface to the second surface; and
a plurality of first protrusions disposed over a central region of the head, wherein each of the plurality of the first protrusions has a first surface in contact with the second surface of the head and a second surface opposite to the first surface, wherein the plurality of the first protrusions comprise a first material and the head comprises a second material, and wherein a step-height is formed between the second surface of the head and the second surfaces of the plurality of the first protrusions.

17. The apparatus of claim 16, wherein a hardness of the second material is different from a hardness of the first material.

18. The apparatus of claim 16, wherein the first material is replaceable.

19. The apparatus of claim 16, further comprising:
a plurality of second protrusions, wherein a thickness of the plurality of the first protrusions is greater than a thickness of the plurality of the second protrusions, and a step-height is formed between a surface of the plurality of the second protrusions and the second surfaces of the plurality of the first protrusions.

20. The apparatus of claim 19, Wherein a hardness of the first material is greater than a hardness of a material of the plurality of the second protrusions.
